(19) United States
(12) Patent Application Publication
(10) Pub. No.: US 2025/0374685 A1
(43) Pub. Date: Dec. 4, 2025

(54) HOLE CONTACT FOR ELECTRONIC AND OPTOELECTRONIC DEVICES

(71) Applicant: ARIZONA BOARD OF REGENTS ON BEHALF OF ARIZONA STATE UNIVERSITY, Scottsdale, AZ (US)

(72) Inventors: Yong-Hang Zhang, Scottsdale, AZ (US); Xin Qi, Tempe, AZ (US); Zheng Ju, Tempe, AZ (US)

(73) Assignee: ARIZONA BOARD OF REGENTS ON BEHALF OF ARIZONA STATE UNIVERSITY, Scottsdale, AZ (US)

(21) Appl. No.: 19/224,677

(22) Filed: May 30, 2025

Related U.S. Application Data
(60) Provisional application No. 63/654,602, filed on May 31, 2024.

(51) Int. Cl. H10F 10/17; H10F 77/123

(52) U.S. Cl. CPC H10F 10/17; H10F 77/1237

(57) ABSTRACT

Junctions and methods of forming junctions are provided. The junction can include an n-type doped semiconductor and a hole-selective contact layer, and the n-type doped semiconductor can include a barrier intrinsic layer. Further, the hole-selective contact layer can be deposited directly on the barrier layer, forming an interface between the hole-selective contact layer and the barrier layer. A composition of the barrier layer is chosen to tailor a Fermi level at the interface such that the Fermi level at the interface is near a valence band edge of the n-type doped semiconductor. The barrier layer can be selected from one of an intrinsic layer and a lightly doped p-type layer.

### CROSS-REFERENCE TO RELATED APPLICATION

This application claims the priority and benefit of U.S. Provisional Application No. 63/654,602, filed on May 31, 2024, which is hereby incorporated by reference in its entirety.

### GOVERNMENT SUPPORT

This invention was made with government support under FA9453-20-2-0011 awarded by the Air Force Research Laboratory. The government has certain rights in the invention.

### FIELD OF THE DISCLOSURE

The present disclosure relates to junctions for electronic devices and optoelectronic devices

### BACKGROUND

Many semiconductors cannot be easily doped either n-type, p-type, or both using conventional methods of introducing dopants into the semiconductors. In addition, semiconductor surfaces and certain interfaces have many electronic states caused by dangling or unsaturated bonds on the surface or at the interface. These states can exhibit a broad spread in energy. For covalent semiconductors, many of these states can be inside of the forbidden gap. Metal contacts to these semiconductor interfaces may exhibit the “Fermi level pinning” effect due to the high density of these states and misalignments of the Fermi levels between the contact metal and the semiconductor.

As an example, the group II-VI binaries and their alloys, (Be Mg Zn Cd Hg) (S Se Te), can have a very broad application in optoelectronic devices, which can include thin-film solar cells, photodetectors ranging from ultraviolet (UV) to longwave infrared (IR), and radiation detectors for x-rays, γ-rays, and neutrons, etc. One challenge for this mature material system is to achieve high quality n- and p-type doping simultaneously. For instance, zinc telluride (ZnTe) and cadmium selenide (CdSe) can be easily doped p-type but not n-type, while cadmium telluride (CdTe) and mercury cadmium telluride (HgCdTe) are easily doped n-type but not p-type. This limitation has made it difficult to make either electron or hole ohmic contacts to these materials.

Polycrystalline Cd(Se)Te thin-film solar cells make up approximately 5% of the global photovoltaics (“PV”) market. A manufacturer of thin-film solar cells, FIRST SOLAR, holds the record power conversion efficiency of 23.1% for CdSeTe cells. This value is lower than the current efficiency of Si cells, 26.7%, and 28%˜30% for the CdSeTe devices.

### SUMMARY

Junctions with large build-in potentials are provided. As used herein, a junction includes both electrical junctions for electronic devices and optoelectronic junctions for use in, for example, solar cells, photodetectors and laser diodes. In an embodiment, a junction, either for electronic or optoelectronic devices, can include an n-type doped semiconductor and a hole-selective contact layer. In an embodiment, the n-type doped semiconductor can include a barrier layer, which can be an intrinsic layer or a lightly doped p-type layer. Further, in an embodiment, the hole-selective contact layer can be a transparent hole-selective contact layer. The hole-selective contact layer, such as an ITO layer or other similar conductive layer using materials with less concentrations compared with metals, can be deposited directly on the barrier layer, forming an interface between the hole-selective contact layer and the barrier layer. In an embodiment, a composition of the barrier layer is chosen to tailor a Fermi level at the interface such that the Fermi level at the interface is near a valence band edge of the n-type doped semiconductor. In an embodiment, the tailored Fermi level at the interface near the valence band edge of the n-type doped semiconductor is sufficient to extract the hole carriers from the barrier. In an embodiment, the barrier layer can be an intrinsic layer or a lightly doped p-type layer.

In a further embodiment, the composition of the intrinsic layer or lightly doped p-type layer is (Mg,Zn)_{X}Cd_{1-X}Te with X taking a value between 0 and 1. In an embodiment, the value of X can be different from both 0 and 1. Further still, in an embodiment, the tailored Fermi level at the interface can have a value less than approximately 0.1 eV from a value of the valence band edge at the interface. In embodiment, it can also be less than any value between approximately 99 meV and 50 meV.

In a further embodiment, the composition of the intrinsic layer can be Mg_{X}Cd_{1-X}Te with X taking a value between 0 and 1. In an embodiment, the value of X can be different from both 0 and 1. Further still, in an embodiment, the value of X can be approximately 0.4.

In addition, in an embodiment, the hole-selective contact layer can be n-type Indium Tin Oxide, and a thickness of the deposited hole-selective contact layer can be approximately 50 nm.

A further embodiment can include any of the previously stated embodiments, but further including a wide bandgap layer between the hole-selective contact layer and the barrier layer (which can be an intrinsic layer or a lightly doped p-type layer) such that the hole selective contact layer is deposited directly on the wide bandgap layer, forming an interface between the hole-selective contact layer, the wide bandgap layer, and the barrier layer.

Methods of forming a junction are also provided. In an embodiment the method can include providing an n-type doped semiconductor, where the n-type doped semiconductor comprises a barrier layer (which can include an intrinsic layer or a lightly doped p-type layer), and can include depositing a hole-selective contact layer directly on the n-type doped semiconductor forming an interface between the hole-selective contact layer and the barrier layer. The hole-selective contact layer can be a transparent hole-selective contact layer. In an embodiment, a composition of the barrier layer is chosen to tailor a Fermi level at the interface such that the Fermi level at the interface is near a valence band edge of the n-type doped semiconductor. In an embodiment, the tailored Fermi level at the interface near the valence band edge of the n-type doped semiconductor is sufficient to extract the hole carriers from the barrier layer.

In a further embodiment, the composition of the intrinsic layer is (Mg,Zn)_{X}Cd_{1-X}Te with X taking a value between 0 and 1. In an embodiment, the value of X can be different from both 0 and 1. Further still, in an embodiment, the tailored Fermi level at the interface can have a value less than approximately 0.1 eV from a value of the valence band edge at the interface. In embodiment, it can also be less than any value between approximately 99 meV and 50 meV.

In a further embodiment, the composition of the intrinsic layer can be Mg_{X}Cd_{1-X}Te with X taking a value between 0 and 1. In an embodiment, the value of X can be different from both 0 and 1. Further still, in an embodiment, the value of X can be approximately 0.4.

In addition, in an embodiment, the hole-selective contact layer can be n-type Indium Tin Oxide, or other similar conductive oxide layers, and a thickness of the deposited transparent hole-selective contact layer can be approximately 50 nm.

A further embodiment can include any of the previously stated methods, but further including a wide bandgap layer between the hole-selective contact layer and the barrier layer such that the hole selective contact layer is deposited directly on the wide bandgap layer, forming an interface between the hole-selective contact layer, the wide bandgap layer, and the barrier layer (where the barrier layer can be an intrinsic layer or a lightly doped p-type layer).

In an embodiment, the n-type semiconductor layer can be a bulk semiconductor and oxides, a double heterostructure, quantum wells, superlattice, or modulation doped heterostructure, which can be used to build electronic devices such as HBT, HEMT, Gunn diodes, etc., and optoelectronic devices such as laser solar cells, photodetectors, laser diodes, and modulator.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 depicts a band diagram of a crystalline cadmium telluride (CdTe) solar cell using a CdTe/magnesium cadmium telluride (MgCdTe) double-heterostructure (DH) design;

FIG. 2 depicts band-edge alignment of an embodiment consistent with this disclosure;

FIG. 3 illustrates a layer structure of a device consistent with this disclosure;

FIGS. 4 and 5 depict C-V measurements and J-V curves, respectively, of the device of FIG. 3;

FIG. 6 depicts excitation-dependent V_{oc} and J_{sc} results of the device of FIG. 3;

FIGS. 7 and 8 depict J-V curves of the device of FIG. 3 at different temperatures and a J-V curve (at a particular temperature) measured 12 months apart;

FIGS. 9 and 10 are schematic diagrams for ITO on a wide-bandgap material (FIG. 9), and ITO on 2D materials for hole-selective contact (FIG. 10);

FIG. 11 depicts band-edge alignment of various 2D materials with CdTe; and

FIGS. 12A-D depict embodiments of an interface consistent with this disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

As used herein, the term “junction” encompasses both electrical junctions for electronic devices and optoelectronic junctions. Optoelectronic junctions include (without limitation) solar cells and photodetectors. In addition, as used herein, the term “barrier layer” encompasses both an intrinsic layer as described and a lightly doped p-type layer.

As used herein, an n-type semiconductor layer can include bulk semiconductor and oxides, a double heterostructure, quantum wells, superlattice, or modulation doped heterostructure. One skilled in the art will appreciate that an n-type semiconductor layer, as used herein, can be used to build electronic devices such as HBT, HEMT, Gunn diodes, etc., and optoelectronic devices such as laser solar cells, photodetectors, laser diodes, and modulator.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

### I. Introduction

Developing CdSeTe thin-film solar cells with greater than 26% efficiency has been a goal. It has been predicted that, under current device designs, further reducing carrier recombination and improving dopant activation will only allow for incremental change and, in any event, can only ultimately provide a device with 25% efficiency. Indeed, the open circuit voltage (V_{oc}) of polycrystalline Cd(Se)Te cells has only improved slightly over a decade. The record of 22.6% efficiency for Cd(Se)Te thin-film solar cells set by FIRST SOLAR in 2024 is a relatively small improvement from 22.1% demonstrated seven years ago in 2016.

Two factors limiting the ability of CdSeTe thin film cells to reach 26%-efficiency include 1) the low dopability of p-type CdSeTe and 2) the low-lying valence band edge of CdSeTe. Together, these factors limit the ability to make a desirable ohmic hole contact. As a result, the V_{oc} of polycrystalline CdSeTe solar cells is only ˜0.9 V, considerably lower than the 1.1 V achieved by monocrystalline CdTe cells. Furthermore, such a low p-type dopability will result in a low built-in voltage (V_{bi}) that may limit the V_{oc} and extraction efficiency of the photogenerated carriers from the absorber. A further drawback is that the state-of-the-art CdSeTe devices use metal back contact. Such monofacial devices cannot fully utilize the scattered solar radiation. In comparison, NREL and FIRST SOLAR have used cracked film lithography (CFL) to build a bifacial CdTe solar cell with a power density of 20.3 mWcm⁻². The cell has a higher bifacial power density than any polycrystalline absorber currently manufactured at scale.

Hole contacts for electronic devices and optoelectronic devices (including solar cells and photodetectors) are provided in this disclosure. Embodiments described herein take advantage of Fermi level engineering (due to surface and/or interface effects) to build an electrical field inside of a semiconductor to extract or inject carriers for electronic devices, solar cells, photodetectors, and other light-emitting device applications. For example, in one embodiment, n-type or p-type two-dimensional (2D) materials can be used in contact with an n-type semiconductor to form a “p-region” so that a p-n junction, or an i-n or n-n+ junction can be constructed. Similarly, in another embodiment, n-type or p-type 2D materials can be used in contact with a p-type semiconductor to form an “n-region” so that an n-p junction, or an i-p or p-p+ junction can be constructed. These structures can provide sufficiently high electrical field inside the semiconductor to extract photogenerated carriers in solar cells and photodetectors or inject minority carriers for light-emitting devices.

In an embodiment, 2D materials consistent with this disclosure are identified herein to provide the above-described semiconductor devices. In an embodiment, Indium tin oxide (ITO) can be put on top of these 2D materials to form practical contacts. Due to high doping concentrations, the ITO and the 2D materials (either n- or p-type) can form an ohmic contact through an n-n junction of an n-p tunnel junction. The non-metallic contacts can be transparent and enable bifacial thin film solar cells, such as with cadmium telluride (CdTe).

Consistent with this disclosure, some embodiments use n+-type ITO on an n-type magnesium cadmium telluride (MgCdTe)/CdTe double-heterostructure (DH) sample to form a junction with high built-in voltage V_{bi} and open circuit voltage V_{oc}. This structure can combine the n-type 2D materials with ITO. This approach can be extended to other n-type conducting materials. The non-metallic contacts can be transparent and enable bifacial thin film, like CdTe, solar cells.

The present disclosure is directed to the application of these approaches to solar cells, CdTe thin film in particular, although embodiments can be applicable to other devices, such as infrared (IR) detectors and radiation detectors, and certain light emitting devices.

### II. Embodiment with n-Type ITO Integrated with a n-Type Absorber to Form a p-n Junction

An embodiment consistent with this disclosure can include devices with a “remote junction” that use n-type Indium Tin Oxide (ITO) as a transparent hole selective contact layer integrated with a n-type absorber to form a p-n junction. Consistent with this disclosure, this approach can enable a bifacial configuration and has the potential to reach 26% efficiency.

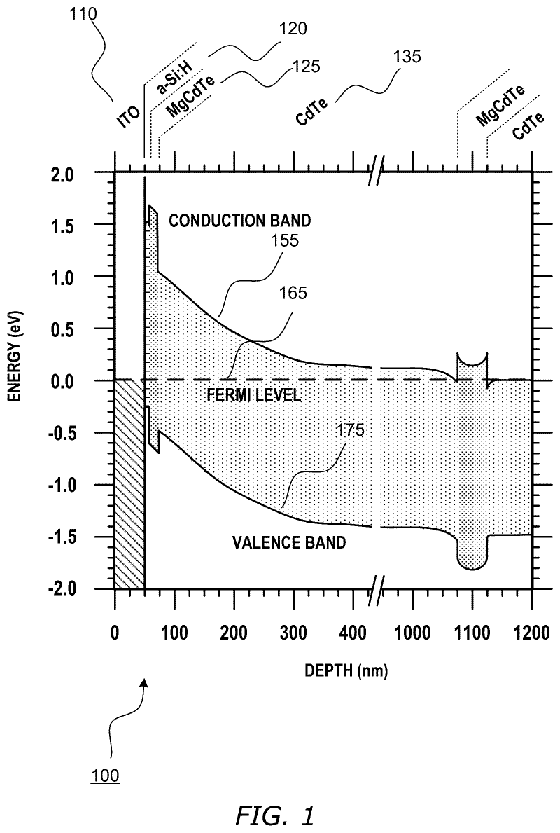

FIG. 1 depicts a device utilizing CdTe/MgCdTe DH (layers 125 and 135) integrated with a metal/ITO/p-aSi:H hole-selective contact layer (layer 120). An advantage of the configuration shown in FIG. 1 includes the use of DH to minimize interfacial recombination and to prevent the minority carriers from reaching the counter-part majority carrier contacts to recombine non-radiatively there. This feature has resulted in a carrier lifetime of 3.6 ρs and a V_{oc} of 1.1 V, which gives a V_{oc} deficiency [W_{oc}≡(E_{g}/q)−V_{oc}] of only 0.4 V, close to the value of 0.3 V and 0.37 V for the state-of-the-art GaAs and Si solar cells, respectively, and much smaller than 0.55 V for polycrystalline CdTe cells. Another advantage of this configuration includes the use of heavily-doped p-aSi:H (layer 120) as the p-type contact, which can lead to a high V_{bi}, thereby enabling a higher Va. Other p-contact layers (ZnTe:As, ZnTe:Cu, and CuZnS) have that have been explored show a higher V_{oc} than that of polycrystalline cells. A drawback of the design of FIG. 1, however, is that the p-aSi:H layer (layer 120) is absorptive to sunlight and lacks long-term stability in air for actual applications.

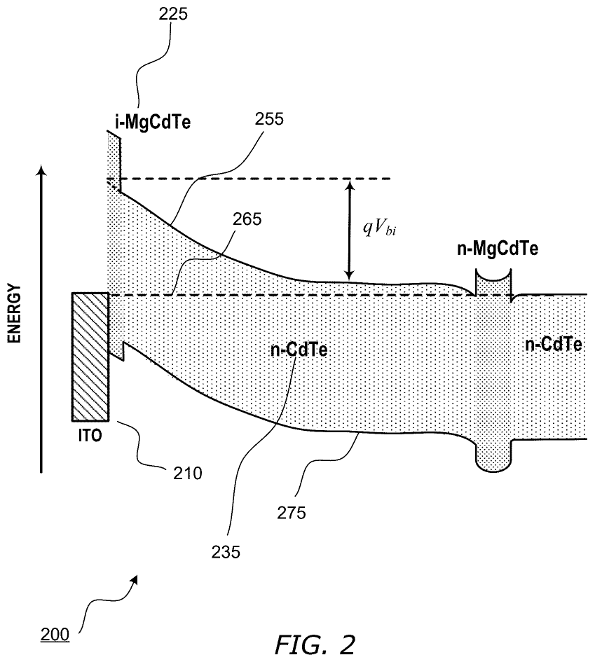

This drawback can be overcome by depositing a 50-nm ITO layer on the MgCdTe layer directly, as shown in FIG. 2. Specifically, the 50-nm ITO layer corresponds to layer 210 and the MgCdTe layer corresponds to layer 225. Further suitable thicknesses and doping concentrations will be apparent to one of ordinary skill in the art.

Specifically, FIG. 2 depicts band edge alignment of a device consistent with this disclosure. The Fermi level (curve 265) of the n-type ITO (layer 210) is engineered to be positioned at the interface such that the ITO (layer 210) acts as a “p-region” and forms a “p-n junction” with the n-type absorber, including n-CdTe (layer 235). In an embodiment, the Fermi level (curve 265) of the n-type ITO (layer 210) is engineered to be positioned at the interface such that the hole carriers can be extracted from the barrier layer (which can include an intrinsic layer and a lightly doped p-type layer). In a further embodiment, the Fermi level (curve 265) of the n-type ITO (layer 210) is engineered to be positioned at the interface such that the value of the Fermi level at the interface is less than approximately 0.1 eV from the value of the valence band edge at the interface.

The use of n-type ITO (layer 210) as p-contact is counterintuitive. Consistent with this embodiment, the disclosed approach takes advantage of the Fermi-level-pinning effect, i.e. the Fermi level (curve 265) of the ITO (layer 210) is pinned near the MgCdTe (layer 225) valence band edge (curve 275) at the interface with MgCdTe (layer 225). The placement of Fermi level 264 near the valence band edge (curve 275 near the interface) can be engineered by varying the Mg composition of the intrinsic layer (i-MgCdTe 225) (or a lightly doped p-type layer). For example, the intrinsic layer can be represented as i-Mg_{X}Cd_{1-X}Te, where X can take on values between 0 and 1. By adjusting X, for example, the Fermi level 264 can be engineered to lie near the valence band edge at the interface (curve 275 near and at the interface). In embodiments, for example, and for particular values of X, the Fermi level 264 can be engineered to lie near and above the valence band edge at the interface. The n-type ITO (layer 210) thus effectively acts as a “p-region” and forms a “p-n junction” with the n-type CdTe/MgCdTe double-heterostructure (DH) absorber (layers 225 and 235), resulting in a high V_{bi} and sufficient electric field inside the absorber to extract photogenerated carriers. A design consistent with this embodiment, using the “remote junction” concept and ITO layer can allow one to bypass the challenge of p-type doping in CdTe, i.e. the whole device structure does not need to have acceptors inside the semiconductor absorber. An approach consistent with this embodiment can also enable low-cost bifacial CdSeTe solar cells with improved power conversion efficiencies as the ITO layer with a bandgap of ˜4 eV is transparent to all visible light. In addition, layer 225 can be a lightly doped p-type later. Results of a monocrystalline CdTe/MgCdTe double-heterostructure solar cells consistent with this disclosure using a transparent hole contact have shown a V_{oc} of 0.99 V and an efficiency of 16.4% without any AR coating.

### III. Results

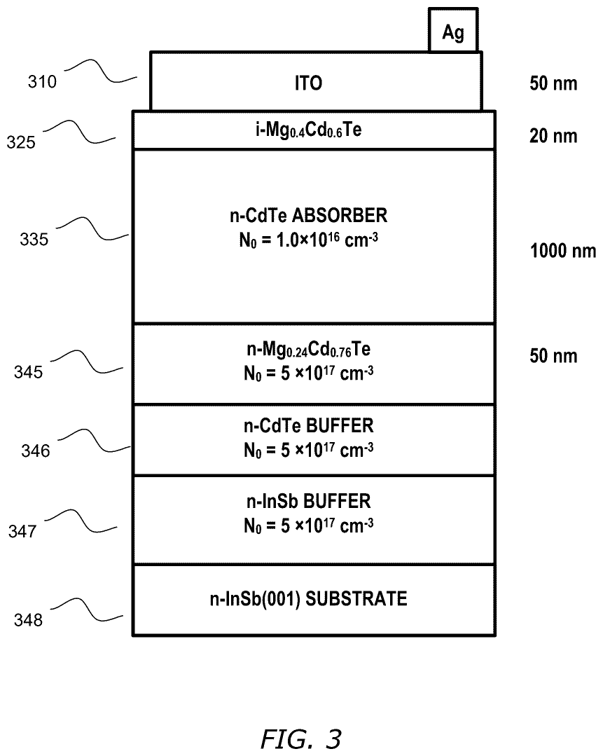

A device layer structure design and doping profile consistent with this disclosure is shown in FIG. 3 (i.e., the CdTe/MgCdTe DH device with ITO as a transparent hole contact). The CdTe/MgCdTe DHs (layers 335 and 325) were grown on nearly-lattice-matched InSb substrates using molecular beam epitaxy (MBE). The MgCdTe barriers (layer 345 and layer 325) can confine the carriers to reduce the surface recombination rate. In an embodiment, the bottom MgCdTe barrier (layer 345) and the bottom CdTe layer (layer 346) were doped n-type with indium, while the top MgCdTe barrier was unintentionally doped.

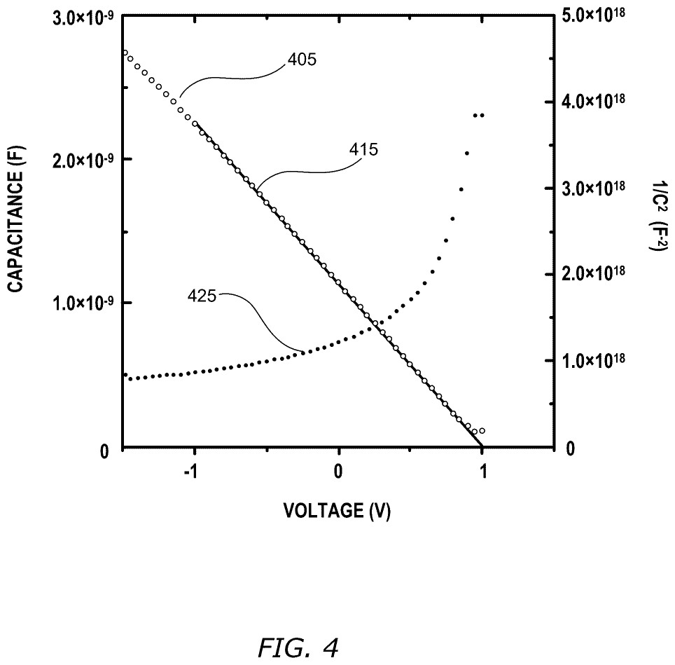

As shown in FIG. 2, the Fermi level at the interface between the ITO and the top MgCdTe barrier is engineered to lie above the valence band edge of the MgCdTe barrier layer. A C-V plot of the device of FIG. 3 is shown in FIG. 4, and a V_{bi} of 1.01 V is extrapolated from the 1/C²-V curve. The Fermi level is pinned at approximately 0.57 eV above the valence band edge of the top MgCdTe barrier layer.

Specifically, FIG. 4 depicts C-V measurement results of the device of FIG. 3. The circles 405 and line 415 are associated with the 1/C² (F⁻²) values on the right-hand side of the plot, and the solid dots 425 are associated with the capacitance values (F) on the left-hand side. The 1.01 V V_{bi} value can be extrapolated from the 1/C²-V curve.

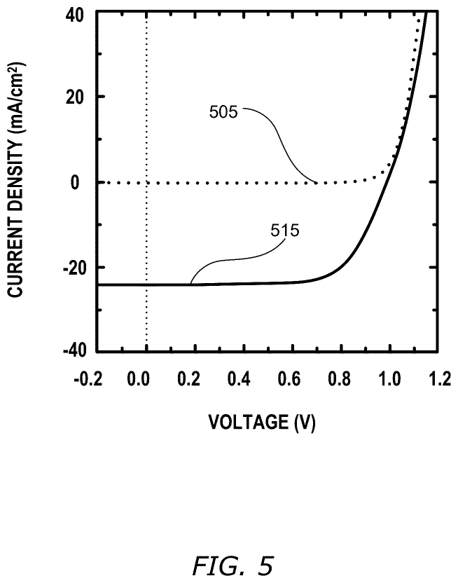

Current density vs. voltage (J-V) curves of the best device in the dark (line 505) and under one-sun illumination (line 515) are shown in FIG. 5. The device exhibits a V_{oc} of 0.99 V and an efficiency of 16.4%. The curve measured in the dark (curve 505) shows a rectifying effect, which is due to the built-in potential inside the device. Under one-sun illumination, the V_{oc} and the fill factor (FF) of the device are 0.99 V and 0.68, respectively, which are close to previous record values for single crystal devices reported in the literature, indicating low bulk nonradiative recombination rates and interface recombination velocities (IRV). The power conversion efficiency is 16.4% for devices without AR coating.

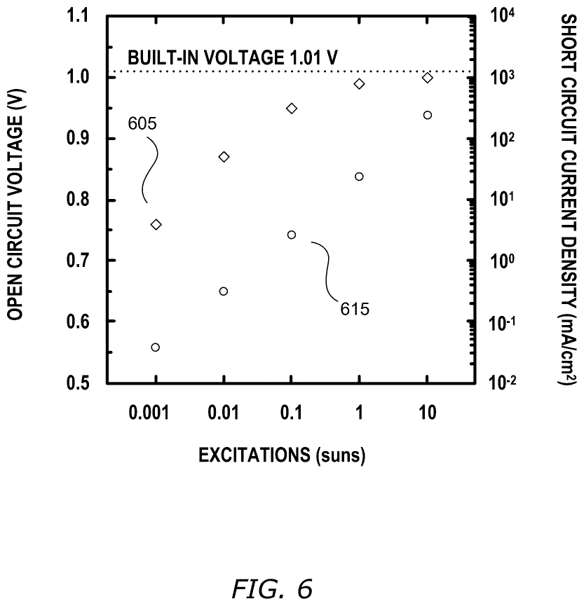

Excitation dependent V_{oc} values (diamonds 605, according to the left-hand scale) and J_{sc} values (circles 615, according to the right-hand scale) are shown in FIG. 6. Under low excitations ranging from 0.001 to 0.1 suns, V_{oc} (diamond 605) increases linearly with the excitation, then saturates and approaches V_{bi} (1.01 V) as the excitation further increases from 0.1 to 10 suns. The J_{sc} (circle 615) is linearly proportional to the excitation power density for the entire range tested. These results are in excellent agreement with the p-n junction theory that V_{bi} limits the V_{oc}, i.e. V_{oc}=V_{bi} when the quasi-Fermi-level splitting inside the absorber is greater than qV_{bi}. Such a high V_{oc} and quasi-Fermi-level splitting is achieved due to the long bulk carrier lifetime and low IRV in the CdTe/MgCdTe DH.

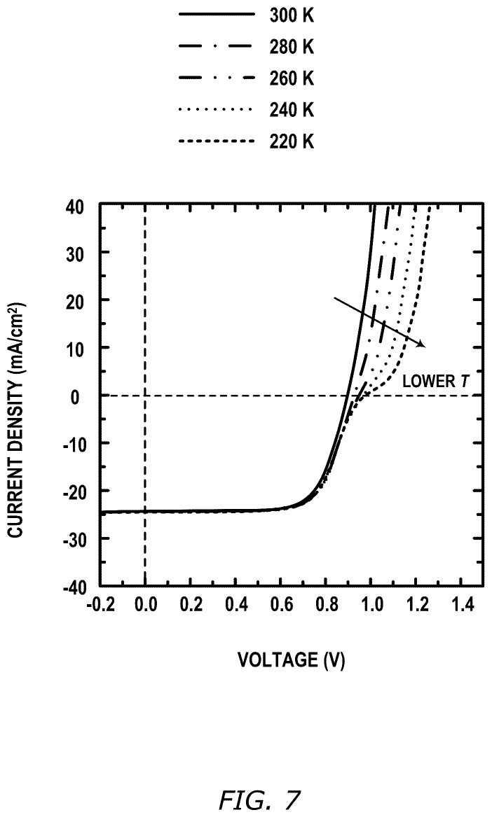

The J-V characteristic behaves as a single PN junction near room temperature, as plotted in FIG. 7. These temperature dependent values are evaluated under an illumination just slightly under 1 sun. When the temperature decreases below 260K, kink behaviors appear in the J-V curves, indicating the hole contact is still not perfectly ohmic at those temperatures. Similar undesirable behavior is also observed in other “remote junction.”

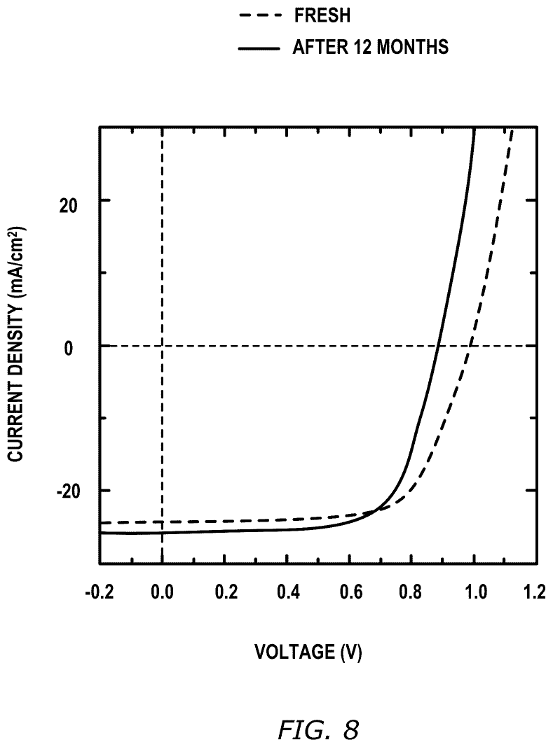

Device stability can be studied by characterizing the photovoltaic performance of the same device stored in a nitrogen box for 12 months. A V_{oc} drop from 0.99 V to 0.89 V is observed. However, the FF remains the same and the J_{sc} even increased by 1.6 mA/cm2 as shown in FIG. 8. The calculated efficiency is 15.7%, 96% of the initial efficiency of 16.4% without AR coating. One of ordinary skill in the art would appreciate that the results of FIG. 8 depict desirable stability.

Devices consistent with this disclosure can demonstrate desirable performance in terms of V_{oc} and conversion efficiency, and can demonstrate a bifacial device with improved efficiency. Further still, outcomes of the disclosed approach can offer better control of the Fermi-level-pinning position and ways to reduce or even eliminate the undesirable Schottky junction at the hole-selective contact, which can remain a challenge for many device designs.

Further aspects of embodiments consistent with this disclosure include: 1) developing the use of the Fermi-level-pinning effect at various interfaces between the ITO and the passivation layer consisting of either a wide-bandgap material or 2D materials with low-lying valence band edges or large work functions; 2) developing combinations of ITO and passivation layers and characterizing performance parameters; and 3) combining a transparent p-contact design with water-soluble liftoff technology to develop a bifacial flexible solar cell.

The first aspect can permit one to “engineer” Fermi level pinning at the interfaces to meet various needs, while the second aspect can utilize findings associated with the “pinned” Fermi-levels to fabricate and configure high performance devices.

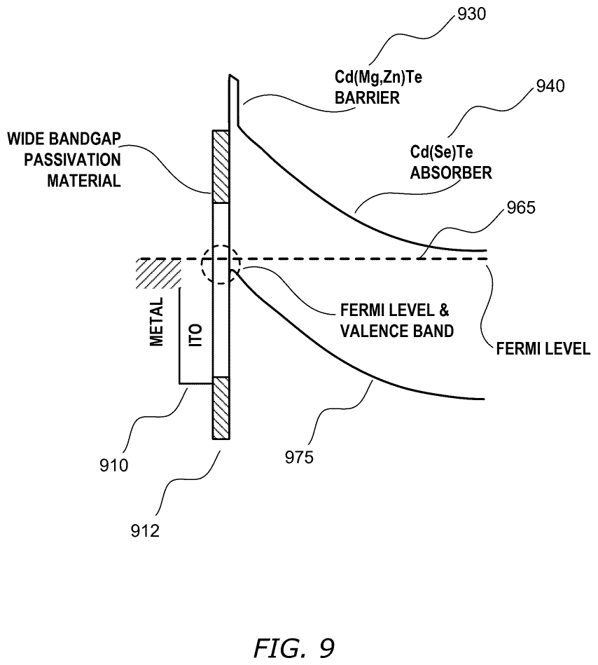

Further aspects of embodiments consistent with this disclosure are shown in FIGS. 9, 10, and 12. For example, wide-bandgap materials (layer 912) with desired Fermi-level pinning can be used to provide a large electrical field in the absorber region, as shown in FIG. 9. Consistent with this disclosure, one can select a material to pin the interface Fermi level at an energy level close to the CdSeTe valence band edge to form a remote “p-n” junction with the n-type absorber. Results have shown that SiO₂, HfO₂, Al₂O₃, TiO₂, and TiN are good passivation layers on CdTe and favorable candidates for this use.

As shown in FIG. 9, layer 910 corresponds to ITO, and layer 912 corresponds a wide bandgap passivation material. Barrier 930 corresponds to a Cd(Mg,Zn)Te barrier and absorber 940 corresponds to Cd(Se)Te absorber. The upper curve is associated with the conduction band and curve 975 is associated with the valence band. Line 965 corresponds to the Fermi level.

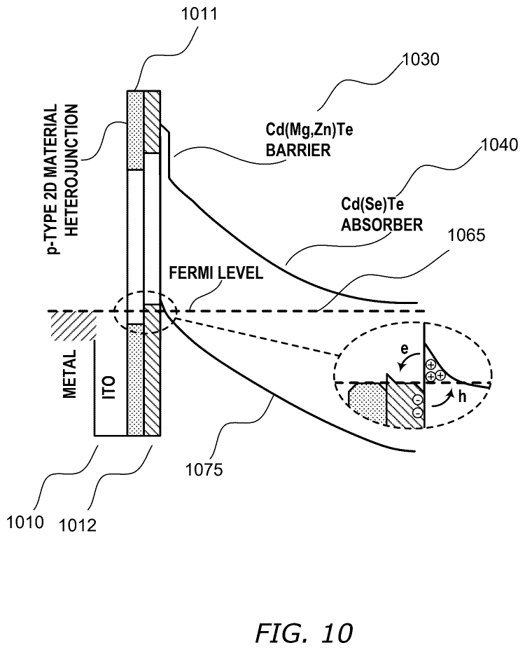

Further aspects of embodiments consistent with this disclosure use a multilayer 2D material heterostructure with large work functions for hole selective contact layer as shown in FIG. 10. A single layer or a double-layer stack of transition-metal oxide (TMO) and dichalcogenides (TMD) [(Mo, W)(O, S, Se, Te)], and GaSe 2D materials can be used to tailor the work-function of the contact layer to realize an ohmic hole selective contact with CdTe. As used herein, this is referred to as “work-function engineering”.

Specifically, FIG. 10 provides a schematic diagram of a p-type 2D material (1011) for hole-selective contact according to embodiments described herein. As shown in FIG. 10, layer 1010 corresponds to ITO, and layer 1011 corresponds to a p type 2D material heterojunction. Barrier 1030 corresponds to a Cd(Mg,Zn)Te barrier and absorber 1040 corresponds to Cd(Se)Te absorber. The upper curve is associated with the conduction band and curve 1075 is associated with the valence band. Line 1065 corresponds to the Fermi level. Consistent with the schematic of FIG. 10, an approach consistent with this disclosure is to use p-type TMO or TMD 2D materials, which have excellent band alignments with CdTe. As shown in the enlargement in FIG. 10, the Fermi level 1065 of the p-contact can then be tailored to align with or below the valence band edge (where curve 1075 is associated with the valence band). Then the holes from the heavily-doped p-type 2D materials like WSe₂ will transfer to the neighboring CdTe, lowering the contact resistance to make it ohmic. The choices of alloy compositions in Cd(Se)Te absorber 1040 and the Cd(Mg,Zn)Te barrier 1030 can make an electron reflector at the interface while maintain a smooth valence band edge.

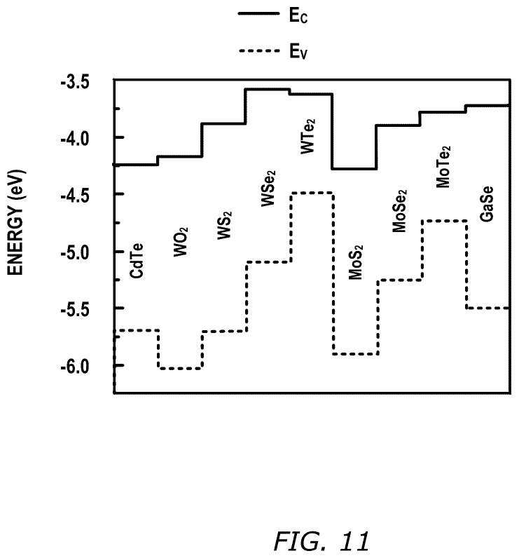

FIG. 11 shows the band-edge alignments of these materials. Consistent with this disclosure, these materials are candidates for the hole-selective contact for CdTe as they have highly desirable band offsets with CdTe.

There are at least sixteen (16) pairing combinations available, such as GaSe/(MoO₂ or MoS₂), WO₂/(WSe₂ or WTe₂), and MoO₂/(WSe₂ or WTe₂). The layer thicknesses will be carefully chosen to tailor the Fermi level of the 2D material stack to properly align with the CdSeTe valence band edge. This unique “tunability” feature is not available for any other known bulk material and is thus a key advantage of the chosen 2D material systems. These materials can be fabricated using chemical vapor deposition (CVD).

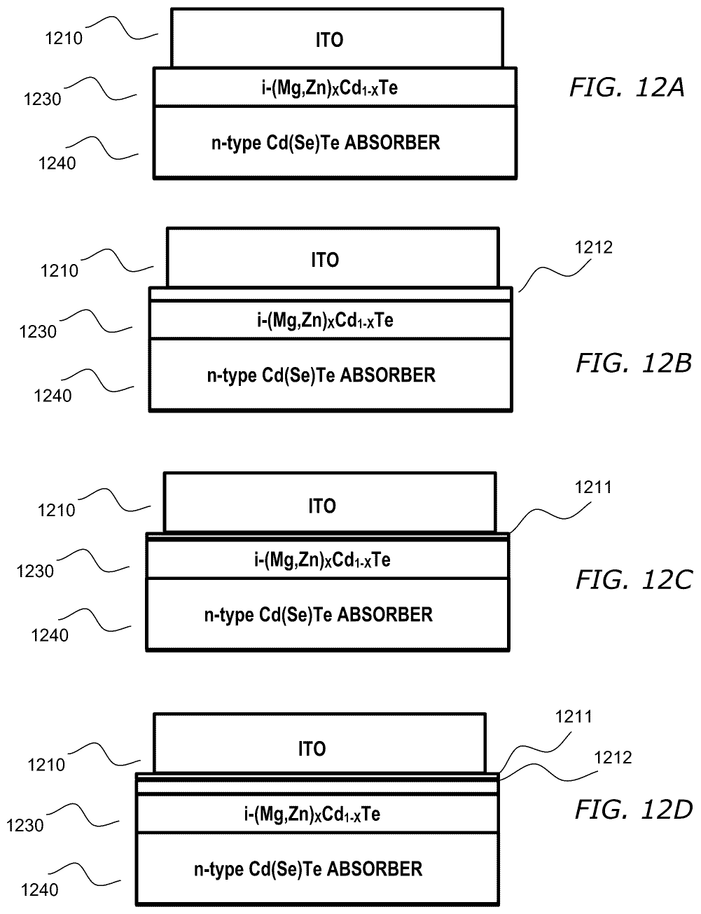

Embodiments consistent with this disclosure are depicted in FIGS. 12A-12D. The embodiment of FIG. 12A depicts a device consistent with the embodiment as discussed in connection with FIGS. 2 and 3. FIG. 12B depicts the device of FIG. 12A, but with wide bandgap passivation material layer 1212 between ITO layer 1210 and barrier layer 1230. FIG. 12C depicts the device of FIG. 12A, but with 2D layer 1211 between ITO layer 1210 and barrier layer 1230. Further still, FIG. 12D depicts the device of FIG. 12A, but with both wide bandgap passivation material layer 1212 and 2D layer 1211 between ITO layer 1210 and barrier layer 1230. Variables that can be adjusted to engineer the placement of the Fermi level include the value of X and the thickness of the 2D layer. As shown in FIG. 10, the Fermi level of the device depicted in FIG. 12D can be engineered to be at or below the valance band edge (curve 1075).

2D material thin films are typically in flakes, which are helpful to concentrate the photocurrent and possess smaller contact areas, and thus reduce the recombination at contact interface as a whole. Furthermore, many of these 2D materials have wider bandgaps than p-aSi:H to minimize the parasitic optical absorption loss. All these advantages drastically improve the V_{oc}, as well as FF and J_{sc}.

Consistent with this disclosure, and based upon the “engineered” Fermi level at the interfaces, one can select combinations of ITO and passivation layers to fabricate devices, which can then be characterized via V_{oc}, FF, and J_{sc} as a function of temperature and excitation to analyze the built-in voltage, interface barrier heights, and their impact on device performance.

Consistent with this disclosure, some 2D material thin films can be in “island” forms, which may act as “point” contacts to concentrate the photocurrent and possess smaller contact areas to reduce possible recombination at the contact interfaces. Furthermore, many of these 2D materials have wider bandgaps than p-aSi:H, minimizing the parasitic optical absorption loss.

In a further aspect consistent with this disclosure, the transparent p-contact design can be combined with water-soluble liftoff technology to fabricate bifacial flexible solar cells. Specifically, a water-soluble liftoff technology consistent with this disclosure includes. Consistent with this disclosure, a structure can be grown on a MgTe sacrificial layer closely lattice-matched to the InSb substrate first, and the hole selective contact layers will be deposited and then the entire device structure will be lifted off using water to etch away the MgTe sacrificial layer, followed by the formation of electron contact to the n-type MgCdTe barrier using ITO.

Those skilled in the art will recognize improvements and modifications to the preferred embodiments of the present disclosure. All such improvements and modifications are considered within the scope of the concepts disclosed herein and the claims that follow.

What is claimed is:

1. A junction, comprising:
an n-type doped semiconductor; and
a hole-selective contact layer;
wherein the n-type doped semiconductor comprises a barrier layer;
wherein the hole-selective contact layer is deposited directly on the barrier layer, forming an interface between the hole-selective contact layer and the intrinsic layer;
wherein a composition of the barrier layer is chosen to tailor a Fermi level at the interface such that the Fermi level at the interface is near a valence band edge of the n-type doped semiconductor;
wherein the tailored Fermi level at the interface near the valence band edge of the n-type doped semiconductor is sufficient to extract the hole carriers from the barrier layer; and
wherein the barrier layer is selected from one of: an intrinsic layer and a lightly doped p-type layer.

2. The junction of claim 1, wherein the barrier layer is the intrinsic layer and the composition of the intrinsic layer is (Mg,Zn)_{X}Cd_{1-X}Te with X taking a value between 0 and 1, and wherein the hole-selective contact layer is a transparent hole-selective contact layer.

3. The junction of claim 1, wherein the tailored Fermi level at the interface has a value less than approximately 0.1 eV from a value of the valence band edge at the interface.

4. The junction of claim 1, wherein the barrier layer is the intrinsic layer and the composition of the intrinsic layer is Mg_{X}Cd_{1-X}Te with X taking a value between 0 and 1.

5. The junction of claim 4, wherein X has a value approximately equal to 0.4.

6. The junction of claim 1, wherein the hole-selective contact layer is n-type Indium Tin Oxide.

7. The junction of claim 6, wherein a thickness of the deposited hole-selective contact layer is approximately 50 nm.

8. A junction, comprising:
an n-type doped semiconductor; and
a hole-selective contact layer;
wherein the n-type doped semiconductor comprises a barrier layer and a wide bandgap layer;
wherein the hole-selective contact layer is deposited directly on the wide bandgap layer, forming an interface between the hole-selective contact layer, the wide bandgap layer, and the barrier layer;
wherein a composition of the barrier layer is chosen to tailor a Fermi level at the interface such that the Fermi level at the interface is near a valence band edge of the n-type doped semiconductor;
wherein the tailored Fermi level at the interface near the valence band edge of the n-type doped semiconductor is sufficient to extract the hole carriers from the barrier layer; and
wherein the barrier layer is selected from one of: an intrinsic layer and a lightly doped p-type layer.

9. The junction of claim 8, wherein the barrier layer is the intrinsic layer and the composition of the intrinsic layer is (Mg,Zn)_{X}Cd_{1-X}Te with X taking a value between 0 and 1, and wherein the hole-selective contact layer is a transparent hole-selective contact layer.

10. The junction of claim 8, wherein the tailored Fermi level at the interface has a value less than approximately 0.1 eV from a value of the valence band edge at the interface.

11. The junction of claim 8, wherein the barrier layer is the intrinsic layer and the composition of the intrinsic layer is Mg_{X}Cd_{1-X}Te with X taking a value between 0 and 1.

12. The junction of claim 11, wherein X has a value approximately equal to 0.4.

13. The junction of claim 8, wherein the hole-selective contact layer is n-type Indium Tin Oxide.

14. The junction of claim 13, wherein a thickness of the deposited hole-selective contact layer is approximately 50 nm.

15. A method for forming a junction in a thin-film device, the method comprising:
providing an n-type doped semiconductor, wherein the n-type doped semiconductor comprises a barrier layer; and
depositing a hole-selective contact layer directly on the n-type doped semiconductor forming an interface between the hole-selective contact layer and the barrier layer; and
wherein a composition of the barrier layer is chosen to tailor a Fermi level at the interface such that the Fermi level at the interface is near a valence band edge of the n-type doped semiconductor; and
wherein the tailored Fermi level at the interface near the valence band edge of the n-type doped semiconductor is sufficient to extract the hole carriers from the barrier layer; and
wherein the barrier layer is selected from one of: an intrinsic layer and a lightly doped p-type layer.

16. The method of claim 15, wherein the barrier layer is the intrinsic layer and the composition of the intrinsic layer is (Mg,Zn)_{X}Cd_{1-X}Te with X taking a value between 0 and 1, and wherein the hole-selective contact layer is a transparent hole-selective contact layer.

17. The method of claim 15, wherein the tailored Fermi level at the interface has a value less than approximately 0.1 eV from a value of the valence band edge at the interface.

18. The method of claim 15, wherein the barrier layer is the intrinsic layer and the composition of the intrinsic layer is Mg_{X}Cd_{1-X}Te with X taking a value between 0 and 1.

19. The method of claim 18, wherein X has a value approximately equal to 0.4.

20. The method of claim 15, wherein the hole-selective contact layer is n-type Indium Tin Oxide.
